(19) United States
(12) Patent Application Publication
(10) Pub. No.: US 2025/0335649 A1
(43) Pub. Date: Oct. 30, 2025

(54) MACHINED SURFACE ESTIMATION DEVICE AND COMPUTER-READABLE STORAGE MEDIUM

(71) Applicant: FANUC CORPORATION, Yamanashi (JP)

(72) Inventor: Tomonobu SUZUKI, Yamanashi (JP)

(21) Appl. No.: 18/696,359

(22) PCT Filed: Oct. 19, 2021
(86) PCT No.: PCT/JP2021/038636

§ 371 Date: Oct. 23, 2024

(51) Int. Cl. G06F 30/17

(52) U.S. Cl. CPC G06F 30/17

(57) ABSTRACT

A machined surface estimation device includes: an acquisition unit acquiring tool position data indicating the position of a tool, tool shape data indicating the shape of the tool, and workpiece shape data indicating the shape of a workpiece; a machining simulation unit executing a machining simulation for drawing the workpiece after machining on the basis of the tool position data, the tool shape data, and the acquired workpiece shape data; a machining information calculation unit calculating at least one type of machining information pertaining to the quality of the machined surface on the basis of the tool position data; a selection unit selecting one type of machining information from among the calculated at least one type of machining information; and a display unit displaying, in combination with the workpiece after machining, the selected one type of machining information.

### TECHNICAL FIELD

The present disclosure relates to a machined surface estimation device and a computer-readable storage medium.

### BACKGROUND ART

In the related art, a numerical controller displays information indicating a path error of a tool on a machined surface of a workpiece drawn by a simulation (Patent Document 1). This enables an operator to visually check how much a path error has occurred at each position on the machined surface. Since the path error is correlated with vibrations occurring during machining, the operator can estimate what kind of vibrations will occur during machining on the basis of the path error. In addition, the operator can estimate the influence of the vibrations on the machined surface.

### CITATION LIST

### Patent Document

Patent Document 1: JP 2020-71734 A

### SUMMARY OF THE INVENTION

### Problem to be Solved by the Invention

However, in some cases, elements other than the path error affect the machined surface. In this case, in the technique according to the related art that visually displays the path error, there is a concern that the quality of the machined surface will not be accurately estimated.

An object of the present disclosure is to provide a machined surface estimation device and a computer-readable storage medium that can accurately estimate the quality of a machined surface.

### Means for Solving Problem

A machined surface estimation device includes: an acquisition unit configured to acquire tool position data indicating a position of a tool, tool shape data indicating a shape of the tool, and workpiece shape data indicating a shape of a workpiece; a machining simulation unit configured to perform a machining simulation to draw the workpiece after machining on the basis of the tool position data, the tool shape data, and the workpiece shape data acquired by the acquisition unit; a machining information calculation unit configured to calculate at least one type of machining information related to a quality of a machined surface on the basis of the tool position data; a selection unit configured to select one type of machining information from the at least one type of machining information calculated by the machining information calculation unit; and a display unit configured to display the one type of machining information selected by the selection unit in combination with the workpiece after machining.

A computer-readable storage medium stores commands that cause a computer to execute: acquiring tool position data indicating a position of a tool, tool shape data indicating a shape of the tool, and workpiece shape data indicating a shape of a workpiece; performing a machining simulation to draw the workpiece after machining on the basis of the acquired tool position data, tool shape data, and workpiece shape data; calculating at least one type of machining information related to a quality of a machined surface on the basis of the tool position data; selecting one type of machining information from the calculated at least one type of machining information; and displaying the selected one type of machining information in combination with the workpiece after machining.

### Effect of the Invention

According to an aspect of the present disclosure, it is possible to accurately estimate the quality of a machined surface.

### BRIEF DESCRIPTION OF DRAWINGS

FIG. 1 is a block diagram illustrating an example of a hardware configuration of a processing machine;

FIG. 2 is a block diagram illustrating an example of functions of a machined surface estimation device;

FIG. 3 is a diagram illustrating an example of tool position data;

FIG. 4A is a diagram illustrating a method for drawing a workpiece;

FIG. 4B is a diagram illustrating the method for drawing a workpiece;

FIG. 4C is a diagram illustrating the method for drawing a workpiece;

FIG. 4D is a diagram illustrating the method for drawing a workpiece;

FIG. 5 is a diagram illustrating an example of a display screen on which a workpiece after machining is displayed;

FIG. 6 is a diagram illustrating an example of a movement path of a tool indicated by the tool position data;

FIG. 7 is a diagram illustrating an example of machining information calculated by a machining information calculation unit;

FIG. 8 is a diagram illustrating an example of the display screen on which the workpiece after machining is displayed;

FIG. 9 is a diagram illustrating an example of the display screen on which the workpiece after machining is displayed; and

FIG. 10 is a flowchart illustrating an example of a machined surface estimation process performed by the machined surface estimation device.

### MODE(S) FOR CARRYING OUT THE INVENTION

Hereinafter, a machined surface estimation device according to an embodiment of the present disclosure will be described with reference to the drawings. In addition, all combinations of features described in the following embodiment are not necessarily required to solve the problems. Further, in some cases, more detailed description than necessary is omitted. Furthermore, the following description of the embodiment and the drawings are provided to enable those skilled in the art to fully understand the present disclosure and are not intended to limit the scope of the claims.

The machined surface estimation device is a device that performs a machined surface estimation process. The machined surface estimation process is a process that performs a machining simulation to display the quality of a machined surface of a workpiece after machining, without actually machining the workpiece. The performance of the machined surface estimation process makes it possible to display machining information related to the quality of the machined surface in combination with the machined surface. The machining simulation is a process that obtains information indicating the shape of the workpiece after machining and displays the obtained information, without machining the workpiece. The machining information will be described in detail below.

The machined surface estimation device is implemented, for example, in a numerical controller that controls a processing machine. The machined surface estimation device may be implemented in a server or a personal computer (PC) that is connected to the numerical controller.

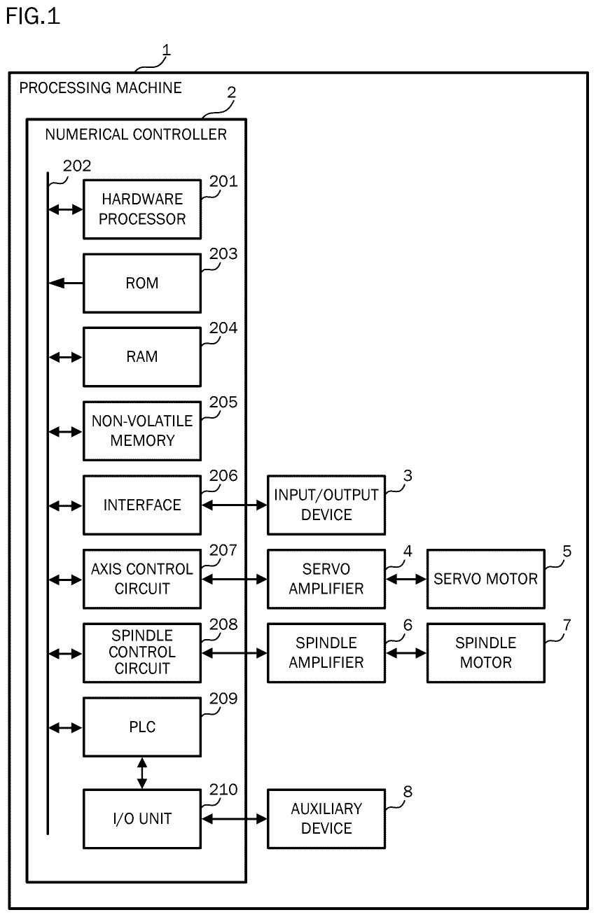

FIG. 1 is a block diagram illustrating an example of a hardware configuration of the processing machine including the numerical controller. A processing machine 1 includes a machine tool, a wire electrical discharge machine, an injection molding machine, and a three-dimensional printer. The machine tool includes a lathe, a machining center, and a multi-tasking machine.

The processing machine 1 includes a numerical controller 2, an input/output device 3, a servo amplifier 4, a servo motor 5, a spindle amplifier 6, a spindle motor 7, and an auxiliary device 8.

The numerical controller 2 is a device that controls the entire processing machine 1. The numerical controller 2 includes a hardware processor 201, a bus 202, a read only memory (ROM) 203, a random access memory (RAM) 204, and a non-volatile memory 205.

The hardware processor 201 is a processor that controls the entire numerical controller 2 according to a system program. The hardware processor 201 reads, for example, the system program stored in the ROM 203 through the bus 202 and performs various processes on the basis of the system program. The hardware processor 201 controls the servo motor 5 and the spindle motor 7 on the basis of a machining program. In addition, the hardware processor 201 performs the machined surface estimation process on the basis of a machined surface estimation program. The hardware processor 201 is, for example, a central processing unit (CPU) or an electronic circuit.

The hardware processor 201 performs, for example, the analysis of the machining program and the output of control commands to the servo motor 5 and spindle motor 7 for each control cycle.

The bus 202 is a communication path that connects each hardware component in the numerical controller 2. Each hardware component in the numerical controller 2 exchanges data through the bus 202.

The ROM 203 is a storage device that stores, for example, the system program for controlling the entire numerical controller 2. The ROM 203 may store the machined surface estimation program. The ROM 203 is a computer-readable storage medium.

The RAM 204 is a storage device that temporarily stores various types of data. The RAM 204 functions as a work area for the hardware processor 201 to process various types of data.

The non-volatile memory 205 is a storage device that retains data even in a state in which the processing machine 1 is turned off and the numerical controller 2 is not supplied with power. The non-volatile memory 205 stores, for example, the machining program and various parameters. The non-volatile memory 205 is a computer-readable storage medium. The non-volatile memory 205 is configured by, for example, a battery backed-up memory or a solid state drive (SSD).

The numerical controller 2 further includes an interface 206, an axis control circuit 207, a spindle control circuit 208, a programmable logic controller (PLC) 209, and an I/O unit 210.

The interface 206 connects the bus 202 and the input/output device 3. The interface 206 transmits, for example, various types of data processed by the hardware processor 201 to the input/output device 3.

The input/output device 3 is a device that receives various types of data through the interface 206 and displays the various types of data. In addition, the input/output device 3 accepts the input of various types of data and transmits the various types of data to, for example, the hardware processor 201 through the interface 206.

The input/output device 3 is, for example, a touch panel. In a case where the input/output device 3 is the touch panel, the input/output device 3 is, for example, a capacitive touch panel. In addition, the touch panel is not limited to the capacitive type and may be a touch panel of another type. The input/output device 3 is installed in an operation panel (not illustrated) in which the numerical controller 2 is stored.

The axis control circuit 207 is a circuit that controls the servo motor 5. The axis control circuit 207 receives a control command from the hardware processor 201 and outputs various commands for driving the servo motor 5 to the servo amplifier 4. The axis control circuit 207 transmits, for example, a torque command to control the torque of the servo motor 5 to the servo amplifier 4.

The servo amplifier 4 receives the command from the axis control circuit 207 and supplies a current to the servo motor 5.

The servo motor 5 receives the current supplied from the servo amplifier 4 and is driven. The servo motor 5 is connected to, for example, a ball screw for driving a tool post. The servo motor 5 is driven to move a structure, such as the tool post, in the processing machine 1 in each axis direction. The servo motor 5 is provided with an encoder (not illustrated) that detects the position and feed rate of a control axis. Position feedback information and speed feedback information that indicate the position of the control axis and the feed rate of the control axis detected by the encoder, respectively, are fed back to the axis control circuit 207. Then, the axis control circuit 207 performs control axis feedback control.

The spindle control circuit 208 is a circuit for controlling the spindle motor 7. The spindle control circuit 208 receives a control command from the hardware processor 201 and outputs a command for driving the spindle motor 7 to the spindle amplifier 6. The spindle control circuit 208 transmits, for example, a spindle speed command for controlling the rotation speed of the spindle motor 7 to the spindle amplifier 6.

The spindle amplifier 6 receives the command from the spindle control circuit 208 and supplies a current to the spindle motor 7.

The spindle motor 7 receives the current supplied from the spindle amplifier 6 and is driven. The spindle motor 7 is connected to a spindle and rotates the spindle.

The PLC 209 is a device that executes a ladder program to control the auxiliary device 8. The PLC 209 transmits a command to the auxiliary device 8 through the I/O unit 210.

The I/O unit 210 is an interface that connects the PLC 209 and the auxiliary device 8. The I/O unit 210 transmits the command received from the PLC 209 to the auxiliary device 8.

The auxiliary device 8 is a device that is installed in the processing machine 1 and performs auxiliary operations in the processing machine 1. The auxiliary device 8 is operated on the basis of the command received from the I/O unit 210. The auxiliary device 8 may be a device that is installed around the processing machine 1. The auxiliary device 8 is, for example, a tool changer, a cutting fluid injection device, or an opening/closing door driving device.

Next, the functions of the machined surface estimation device will be described.

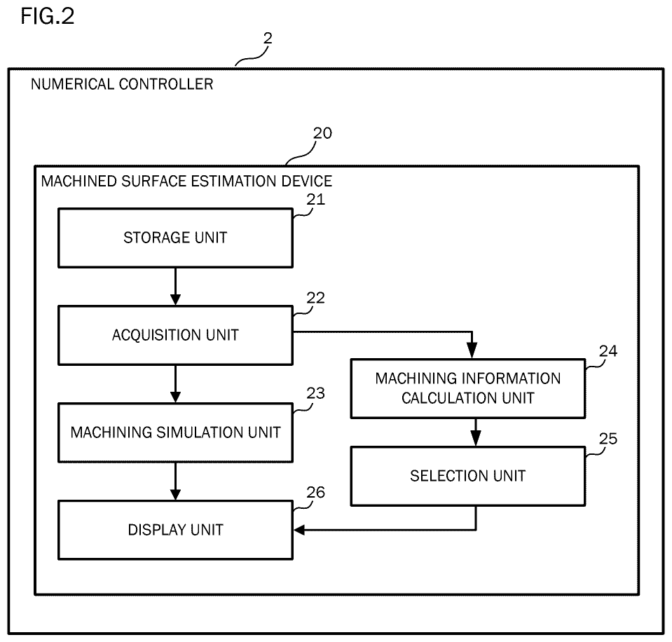

FIG. 2 is a block diagram illustrating an example of the functions of the machined surface estimation device implemented in the numerical controller 2. The machined surface estimation device includes a storage unit 21, an acquisition unit 22, a machining simulation unit 23, a machining information calculation unit 24, a selection unit 25, and a display unit 26.

The storage unit 21 is implemented, for example, by storing various types of data used for the machined surface estimation process in the RAM 204 or the non-volatile memory 205. For example, the acquisition unit 22, the machining simulation unit 23, the machining information calculation unit 24, the selection unit 25, and the display unit 26 are implemented by the hardware processor 201 performing arithmetic processing, using the system program stored in the ROM 203 and various types of data stored in the non-volatile memory 205.

The storage unit 21 stores various types of data used for the machined surface estimation process. The storage unit 21 stores, for example, tool shape data indicating the shape of a tool and workpiece shape data indicating the shape of a workpiece.

The tool shape data includes, for example, data indicating a tool type, a blade diameter, a blade length, a shank diameter, and an overall length. The tool shape data may be three-dimensional model data indicating the shape of the tool.

The workpiece shape data is data indicating the shape and size of the workpiece before machining. The workpiece shape data is, for example, three-dimensional model data.

The acquisition unit 22 acquires tool position data indicating the position of the tool, the tool shape data indicating the shape of the tool, and the workpiece shape data indicating the shape of the workpiece.

The tool position data is data indicating the position of the control axis. The tool position data is, for example, feedback data from a detector that detects the position of the control axis. In this case, the acquisition unit 22 acquires the tool position data from the detector that detects the position of the control axis every predetermined sampling time. That is, the tool position data acquired by the acquisition unit 22 is time-series data.

The detector includes the servo motor 5. The detector may be a linear encoder that is installed along each linear axis of the processing machine 1 or a rotary encoder that is installed around each rotation axis.

The tool position data may be data indicating a coordinate value in a predetermined coordinate system that has been converted from the feedback data. The tool position data may include, for example, data indicating the positions of the X-axis, the Y-axis, and the Z-axis in an orthogonal coordinate system. The orthogonal coordinate system may be a machine coordinate system or a workpiece coordinate system.

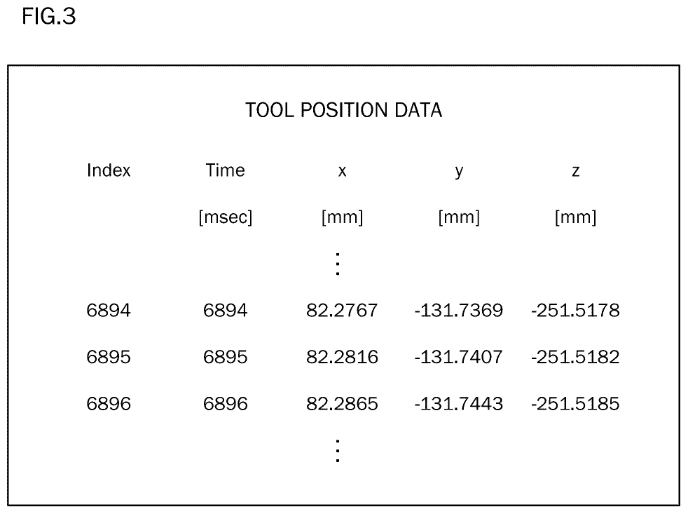

FIG. 3 is a diagram illustrating an example of the tool position data. In the example illustrated in FIG. 3, the acquisition unit 22 acquires the tool position data every 1 [msec].

The tool position data indicates that the tool is at a position of X82.2767 [mm], Y−131.7369 [mm], and Z−251.5178 [mm] at 6894 [msec]. In addition, the tool position data indicates that the tool is at a position of X82.2816 [mm], Y−131.7407 [mm], and Z−251.5182 [mm] at 6895 [msec]. Further, the tool position data indicates that the tool is at a position of X82.2865 [mm], Y−131.7443 [mm], and Z−251.5185 [mm] at 6896 [msec]. Furthermore, “Index” is index information for specifying the position of the tool at each time point.

The acquisition unit 22 acquires the tool shape data and the workpiece shape data from the storage unit 21. The acquisition unit 22 acquires, for example, a tool number designated by a tool selection command in the machining program. The acquisition unit 22 acquires the tool shape data of the tool corresponding to the acquired tool number from the storage unit 21.

For example, the acquisition unit 22 acquires the workpiece shape data on the basis of information designating the workpiece that has been input from the input/output device 3. The acquisition unit 22 may acquire a workpiece number specifying the workpiece designated in the machining program. In this case, the acquisition unit 22 acquires the workpiece shape data of the workpiece corresponding to the acquired workpiece number from the storage unit 21.

The machining simulation unit 23 performs the machining simulation that draws the workpiece during and after machining on the basis of the tool position data, the tool shape data, and the workpiece shape data acquired by the acquisition unit 22. For example, the machining simulation unit 23 calculates three-dimensional model data indicating the shape of the workpiece during and after machining on the basis of the tool position data, the tool shape data, and the workpiece shape data. The machining simulation unit 23 draws the workpiece during and after machining on the basis of this three-dimensional model data. The three-dimensional model is, for example, a patch model.

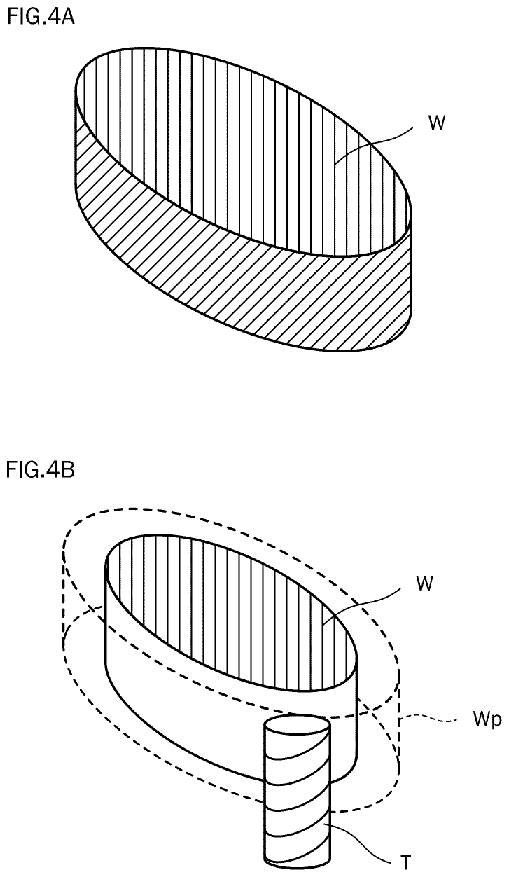

FIGS. 4A to 4D are diagrams illustrating how the machining simulation unit 23 draws the workpiece. The machining simulation unit 23 draws a workpiece W before machining using, for example, the patch model (see FIG. 4A).

Then, the machining simulation unit 23 specifies a portion Wp removed from the workpiece W according to the movement of the tool T (see FIG. 4B).

Then, the machining simulation unit 23 deletes a surface patch of the removed portion Wp (see FIG. 4C).

Then, the machining simulation unit 23 adds new surface patches Pa1 to Pa8 to the patch model so as to close a boundary portion between the portion Wp removed from the workpiece W and the remaining portion of the workpiece W (see FIG. 4D).

The machining simulation unit 23 draws the workpiece W after machining according to the order of “Indexes”. For example, in a case where drawing advances from Index “6894” to Index “6895” illustrated in FIG. 3, the machining simulation unit 23 adds the surface patches Pa1 to Pa4 illustrated in FIG. 4D to the patch model. That is, when Index advances by one, the machining simulation unit 23 generates a plurality of surface patches and adds the plurality of surface patches to the patch model. Further, in a case where drawing advances from Index “6895” to Index “6896” illustrated in FIG. 3, the machining simulation unit 23 adds the surface patches Pa5 to Pa8 illustrated in FIG. 4D to the patch model. Machining information is added to the generated surface patches by the display unit 26, which will be described in detail below.

The machining simulation unit 23 may give a patch number for identifying each of the surface patches Pa1 to Pa8 to each of the surface patches Pa1 to Pa8.

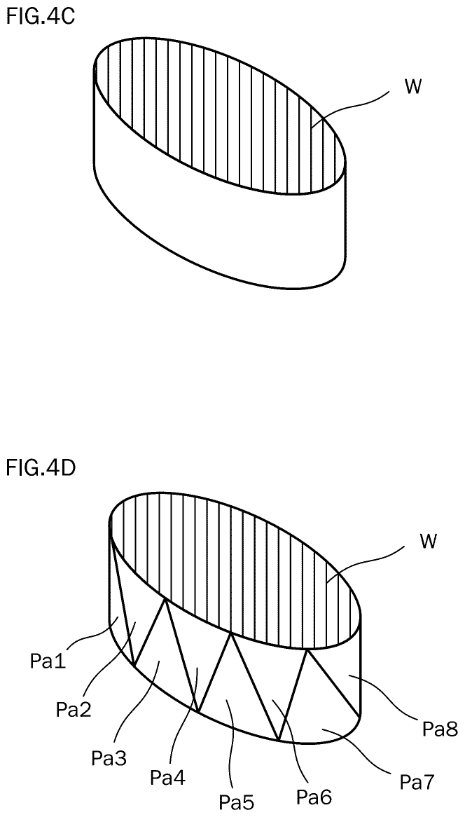

FIG. 5 is a diagram illustrating an example of a display screen on which the workpiece W after machining drawn by the machining simulation unit 23 is displayed. The machining simulation unit 23 draws the workpiece W after machining, for example, when the workpiece W is viewed from a positive direction to a negative direction of the Z-axis. In addition, diagonal lines drawn on the workpiece W in FIG. 5 are given in order to represent shadows.

The machining simulation unit 23 may draw the workpiece W before and during machining. The machining simulation unit 23 may draw the tool T and a movement trajectory indicating a movement path of the tool T. The machining simulation unit 23 may draw the workpiece W before machining, during machining, and after machining when the workpiece W is viewed from various directions.

The machining information calculation unit 24 calculates at least one type of machining information related to the quality of the machined surface on the basis of the tool position data. The at least one type of machining information related to the quality of the machined surface is, for example, information indicating a path error of the tool T, a moving speed of the tool T, an acceleration of the tool T, and a jerk of the tool T. Examples of the quality of the machined surface include a shape error, dimensional error, surface roughness, flatness, and gloss of the machined surface. That is, the path error of the tool T, the moving speed of the tool T, the acceleration of the tool T, and the jerk of the tool T affect the quality of the machined surface and are used to estimate the quality of the machined surface.

The machining information calculation unit 24 calculates the path error of the tool T on the basis of command data indicating the movement path of the tool T designated in the machining program and the tool position data acquired by the acquisition unit 22. That is, the path error is a difference between an ideal movement path of the tool T and an actual movement path of the tool T.

The machining information calculation unit 24 calculates the moving speed of the tool T, the acceleration of the tool T, and the jerk of the tool T on the basis of the tool position data acquired every predetermined sampling time. Here, how the machining information calculation unit 24 calculates the moving speed of the tool T, the acceleration of the tool T, and the jerk of the tool T on the basis of the tool position data will be described.

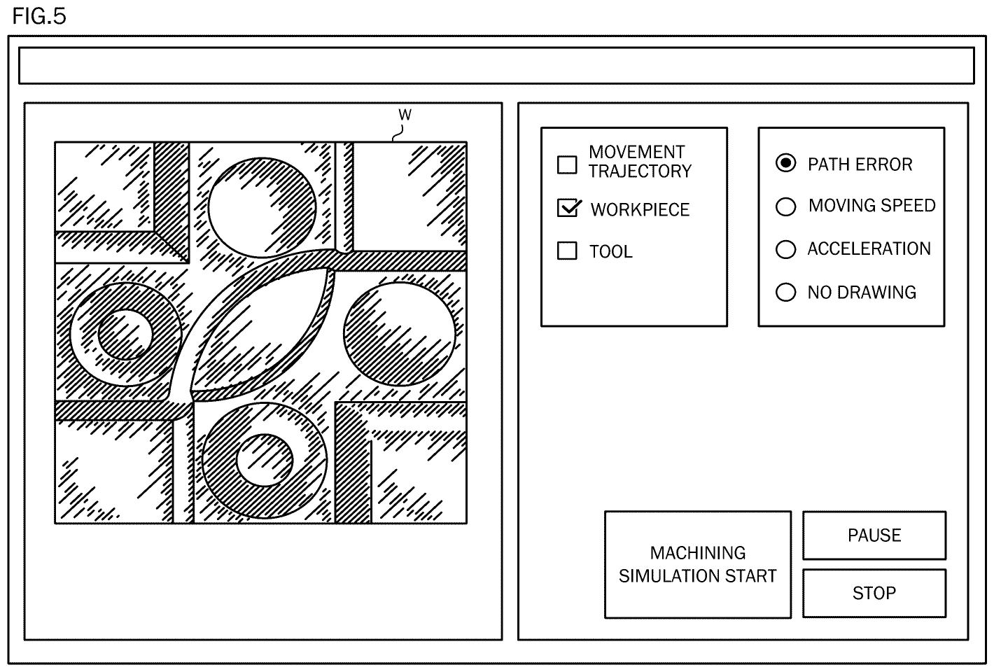

FIG. 6 is a diagram illustrating an example of the movement path of the tool T indicated by the tool position data. FIG. 6 illustrates that the tool T is moved from a position indicated by Pn−1 to a position indicated by Pn during Δt [msec] and is then moved from the position indicated by Pn to a position indicated by Pn+1 during the next Δt [msec].

In this case, the machining information calculation unit 24 calculates the moving speed of the tool T using the following Expression 1.

$${v}_{n} = \frac{\vert {P}_{n} - {P}_{n - 1} \vert}{Δ t} \qquad [ Expression 1 ]$$

Here, P is the position of the tool T, Δt is the sampling time, and v is the moving speed of the tool T.

Further, the machining information calculation unit 24 calculates the acceleration of the tool T using the following Expression 2.

$${a}_{n} = \frac{{v}_{n} - {v}_{n - 1}}{Δ t} \qquad [ Expression 2 ]$$

Here, a is the acceleration of the tool T.

Furthermore, the machining information calculation unit 24 calculates the jerk of the tool T using the following Expression (3).

$${j}_{n} = \frac{{a}_{n} - {a}_{n - 1}}{Δ t} \qquad [ Expression 3 ]$$

Here, j is the jerk.

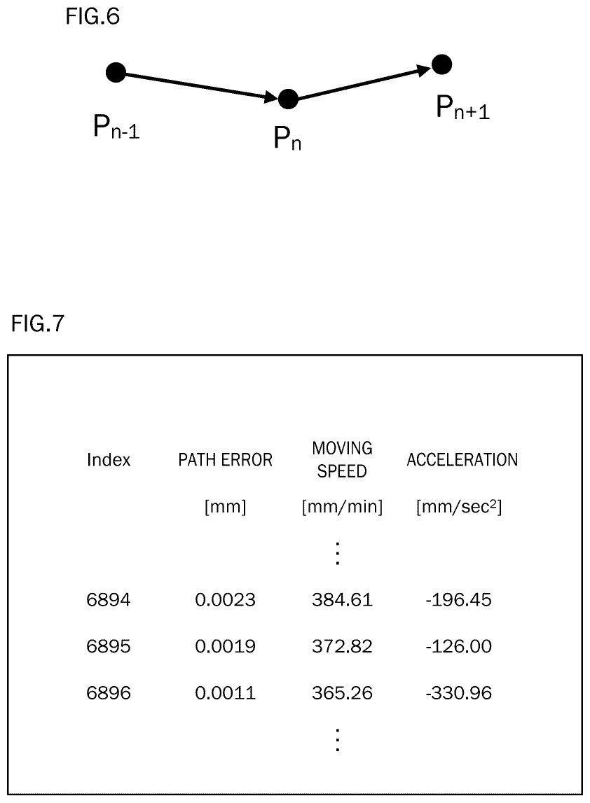

FIG. 7 is a diagram illustrating an example of the machining information calculated by the machining information calculation unit 24. FIG. 7 illustrates the machining information calculated in a case where the tool position data illustrated in FIG. 3 is acquired.

Specifically, the path error of the tool T, the moving speed of the tool T, and the acceleration of the tool T at Index “6894” are 0.0023 [mm], 384.61 [mm/min], and −196.45 [mm/sec²], respectively. In addition, the path error of the tool T, the moving speed of the tool T, and the acceleration of the tool T at Index “6895” are 0.0019 [mm], 372.82 [mm/min], and −126.00 [mm/sec²], respectively. Furthermore, the path error of the tool T, the moving speed of the tool T, and the acceleration of the tool T at Index “6896” are 0.0011 [mm], 365.26 [mm/min], and −330.96 [mm/sec²], respectively.

The selection unit 25 selects one type of machining information from the at least one type of machining information calculated by the machining information calculation unit 24. The machined surface estimation device receives, for example, information indicating which machining information has been selected among a plurality of types of machining information from the input/output device 3. The machined surface estimation device receives, for example, information indicating which of the path error of the tool T, the moving speed of the tool T, the acceleration of the tool T, and the jerk of the tool T has been selected. The selection unit 25 selects one type of machining information on the basis of the information received from the input/output device 3.

The display unit 26 displays the one type of machining information selected by the selection unit 25 in combination with the workpiece W after machining. The display unit 26 displays the machining information at the position indicated by the tool position data used for calculating the machining information. Alternatively, the display unit 26 may display the machining information near the position indicated by the tool position data used for calculating the machining information. For example, the display unit 26 displays the workpiece W after machining on the display screen of the input/output device 3.

For example, the display unit 26 combines the machining information with each of the surface patches Pa1 to Pa8. For example, the machining information is represented by a plurality of different colors. For example, the display unit 26 colors the surface patches Pa1 to Pa8 given to the workpiece W after machining to display one type of machining information.

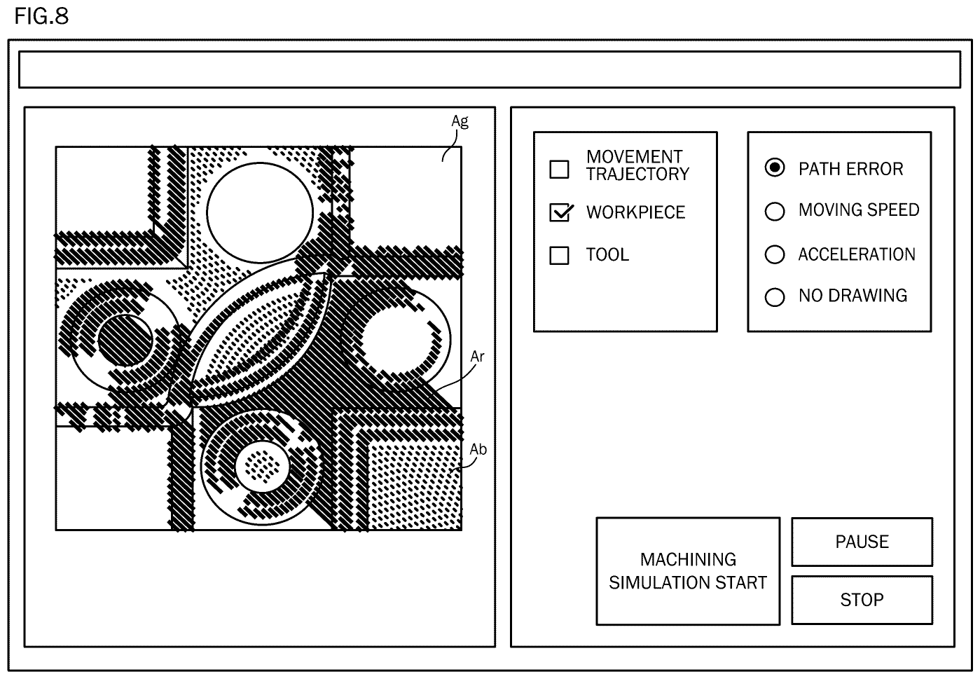

FIG. 8 is a diagram illustrating an example of the display screen on which the workpiece W after machining is displayed by the display unit 26. In addition, FIG. 8 illustrates a display aspect of the workpiece W in a case where the selection unit 25 selects the path error of the tool T as the machining information.

For example, the display unit 26 displays a portion Ar, in which the magnitude of the path error of the tool T is equal to or greater than −0.5 [mm] and less than −0.001 [mm], in red. In addition, the display unit 26 displays a portion Ag, in which the magnitude of the path error is equal to or greater than −0.001 [mm] and less than 0.001 [mm], in green. Further, the display unit 26 displays a portion Ab, in which the magnitude of the path error is equal to or greater than 0.001 [mm] and less than 0.5 [mm], in blue. This enables an operator to visually check the magnitude of the path error.

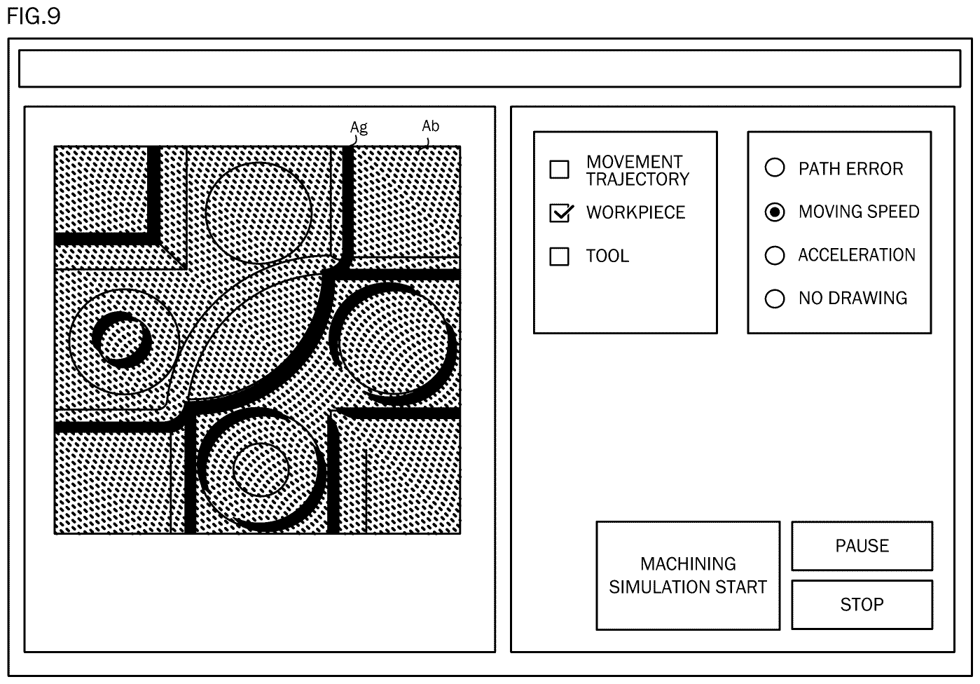

FIG. 9 is a diagram illustrating an example of the display screen on which the workpiece W after machining is displayed by the display unit 26. Moreover, FIG. 9 illustrates a display aspect of the workpiece W in a case where the selection unit 25 selects the moving speed of the tool T as the machining information.

For example, the display unit 26 displays a portion, which has been machined under the condition that the moving speed of the tool T is equal to or greater than 0 [mm/min] and less than 1000 [mm/min], in red. In the example illustrated in FIG. 9, there is no portion machined under the condition that the moving speed of the tool is equal to or greater than 0 [mm/min] and less than 1000 [mm/min]. The display unit 26 displays a portion Ag, which has been machined under the condition that the moving speed of the tool T is equal to or greater than 1000 [mm/min] and less than 1500 [mm/min], in green. Further, the display unit 26 displays a portion Ab, which has been machined under the condition that the moving speed of the tool T is equal to or greater than 1500 [mm/min] and less than 2000 [mm/min], in blue. This enables the operator to visually check the magnitude of the moving speed of the tool T.

Next, the process performed by the machined surface estimation device will be described.

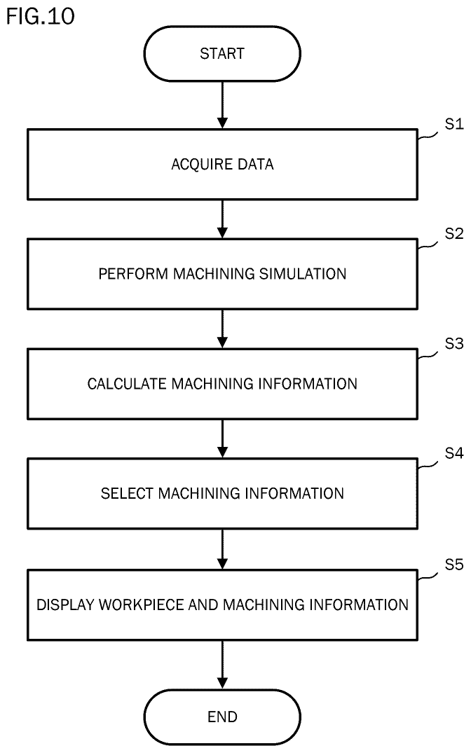

FIG. 10 is a flowchart illustrating an example of the machined surface estimation process performed by the machining surface estimation device. When the numerical controller 2 starts the control of the processing machine 1 on the basis of the machining program, the acquisition unit 22 acquires the tool position data indicating the position of the tool T, the tool shape data indicating the shape of the tool T, and the workpiece shape data indicating the shape of the workpiece W (Step S1). At this time, the workpiece W may not be placed on the table, and the tool T may not machine the workpiece W.

Then, the machining simulation unit 23 performs the machining simulation to draw the workpiece W after machining on the basis of the tool position data, the tool shape data, and the workpiece shape data acquired by the acquisition unit 22 (Step S2).

Then, the machining information calculation unit 24 calculates at least one type of machining information related to the quality of the machined surface on the basis of the tool position data (Step S3).

Then, the selection unit 25 selects one type of machining information from the at least one type of machining information calculated by the machining information calculation unit 24 (Step S4).

Then, the display unit 26 displays the one type of machining information selected by the selection unit 25 in combination with the workpiece W after machining (Step S5). Then, the process ends.

As described above, the machined surface estimation device includes the acquisition unit 22 that acquires the tool position data indicating the position of the tool T, the tool shape data indicating the shape of the tool T, and the workpiece shape data indicating the shape of the workpiece W, the machining simulation unit 23 that performs the machining simulation to draw the workpiece W after machining on the basis of the tool position data, the tool shape data, and the workpiece shape data acquired by the acquisition unit 22, the machining information calculation unit 24 that calculates at least one type of machining information related to the quality of the machined surface on the basis of the tool position data, the selection unit 25 that selects one type of machining information from the at least one type of machining information calculated by the machining information calculation unit 24, and the display unit 26 that displays the one type of machining information selected by the selection unit 25 in combination with the workpiece W after machining.

Therefore, the machined surface estimation device can display the machining information in combination with the workpiece W after machining. As a result, the operator can visually check the machining information to accurately estimate the quality of the machined surface. For example, the operator can predict a position where the quality of the machined surface deteriorates on the machined surface.

Further, the at least one type of machining information includes any one of the path error of the tool T, the moving speed of the tool T, the acceleration of the tool T, and the jerk of the tool T. Therefore, the machined surface estimation device can display the machining information. As a result, the operator can estimate the quality of the machined surface on the basis of the machining information.

Furthermore, the tool position data is feedback data from the detector that detects the position of the control axis. Therefore, the machined surface estimation device can present machining information with higher accuracy than that in a case where the machining simulation is performed on the basis of command values designated in the machining program. As a result, the operator can accurately estimate the quality of the machined surface.

Moreover, the display unit 26 colors the surface of the workpiece W after machining to display one type of machining information. Therefore, the machined surface estimation device can help the operator to intuitively estimate the quality of the machined surface.

In the above-described embodiment, the machining simulation unit 23 draws the workpiece W after machining using the patch model. However, the machining simulation unit 23 may draw the workpiece W after machining using not only the patch model but also other models such as a polygon model and a solid model.

In the above-described embodiment, the display unit 26 gives a plurality of colors to the surface of the workpiece W to display one type of machining information. However, the display unit 26 may display one type of machining information not only using the method of giving a plurality of colors but also using other methods. For example, the display unit 26 may display the machining information using color shading. Further, the display unit 26 may give different patterns to the surface of the workpiece W to display one type of machining information. Furthermore, the display unit 26 may give numbers to the surface of the workpiece W to display one type of machining information.

In the above-described embodiment, the machined surface estimation device displays the machining information, such as the path error of the tool T, the moving speed of the tool T, the acceleration of the tool T, and the jerk of the tool T, in combination with the workpiece W. However, the machined surface estimation device may calculate information indicating the quality of the machined surface, such as the roughness, flatness, and gloss of the machined surface, from the machining information. In this case, the machined surface estimation device performs supervised learning using training data that has the machining information as input data and that has the information indicating the quality of the machined surface as output data. This makes it possible for the machined surface estimation device to generate a trained model indicating the correlation between the machining information and the information indicating the quality of the machined surface. The machined surface estimation device calculates the information indicating the quality of the machined surface from the machining information using the trained model.

In addition, the present disclosure is not limited to the above-described embodiment and can be modified as appropriate without departing from the gist of the present disclosure. In the present disclosure, it is possible to modify any component of the embodiment or to omit any component of the embodiment.

### EXPLANATIONS OF LETTERS OR NUMERALS

1 PROCESSING MACHINE
2 NUMERICAL CONTROLLER
21 STORAGE UNIT
22 ACQUISITION UNIT
23 MACHINING SIMULATION UNIT
24 MACHINING INFORMATION CALCULATION UNIT
25 SELECTION UNIT
26 DISPLAY UNIT
201 HARDWARE PROCESSOR
202 BUS
203 ROM
204 RAM
205 NON-VOLATILE MEMORY
206 INTERFACE
207 AXIS CONTROL CIRCUIT
208 SPINDLE CONTROL CIRCUIT
209 PLC
210 I/O UNIT
3 INPUT/OUTPUT DEVICE
4 SERVO AMPLIFIER
5 SERVO MOTOR
6 SPINDLE AMPLIFIER
7 SPINDLE MOTOR
8 AUXILIARY DEVICE
W WORKPIECE
T TOOL
Wp REMOVED PORTION
Pa1 to Pa8 SURFACE PATCH

1. A machined surface estimation device comprising:
an acquisition unit configured to acquire tool position data indicating a position of a tool, tool shape data indicating a shape of the tool, and workpiece shape data indicating a shape of a workpiece;
a machining simulation unit configured to perform a machining simulation to draw the workpiece after machining on the basis of the tool position data, the tool shape data, and the workpiece shape data acquired by the acquisition unit;
a machining information calculation unit configured to calculate at least one type of machining information related to a quality of a machined surface on the basis of the tool position data;
a selection unit configured to select one type of machining information from the at least one type of machining information calculated by the machining information calculation unit; and
a display unit configured to display the one type of machining information selected by the selection unit in combination with the workpiece after machining.

2. The machined surface estimation device according to claim 1,
wherein the at least one type of machining information includes any one of a path error of the tool, a moving speed of the tool, an acceleration of the tool, and a jerk of the tool.

3. The machined surface estimation device according to claim 1,
wherein the tool position data is feedback data from a detector configured to detect a position of a control axis.

4. The machined surface estimation device according to claim 1,
wherein the display unit is configured to color a surface of the workpiece after machining to display the one type of machining information.

5. A computer-readable storage medium storing commands causing a computer to execute:
acquiring tool position data indicating a position of a tool, tool shape data indicating a shape of the tool, and workpiece shape data indicating a shape of a workpiece;
performing a machining simulation to draw the workpiece after machining on the basis of the acquired tool position data, tool shape data, and workpiece shape data;
calculating at least one type of machining information related to a quality of a machined surface on the basis of the tool position data;
selecting one type of machining information from the calculated at least one type of machining information; and
displaying the selected one type of machining information in combination with the workpiece after machining.
